(19) United States
(12) Patent Application Publication
(10) Pub. No.: US 2025/0040351 A1
(43) Pub. Date: Jan. 30, 2025

(54) DISPLAY DEVICE

(71) Applicant: Samsung Display Co., LTD., Yongin-si (KR)

(72) Inventors: Che Ho LEE, Yongin-si (KR); So Yeon JEONG, Yongin-si (KR); Won Je JO, Yongin-si (KR)

(21) Appl. No.: 18/613,395

(22) Filed: Mar. 22, 2024

(30) Foreign Application Priority Data
Jul. 24, 2023 (KR) 10-2023-0095892

(51) Int. Cl. H10K 59/122; H10K 59/80

(52) U.S. Cl. CPC H10K 59/122; H10K 59/873

(57) ABSTRACT

A display device includes a substrate including emission non-emission areas; an anode electrode on the emission area of the substrate; a pixel defining layer on the anode electrode and overlapping the non-emission area, with a first opening defined therethrough; a first bank structure on the pixel defining layer, and including at least two conductive materials, with a second opening defined therethrough; a second bank structure on the first bank structure and including at least two materials; and a first encapsulation layer on the second bank structure, where the first bank structure includes a first bank layer and a second bank layer including a first tip protruding toward a center of the first opening, the second bank structure includes a third bank layer and a fourth bank layer including a 10 second tip protruding toward a center of the second opening, and the first encapsulation layer covers the first and second tips.

This application claims priority to Korean Patent Application No. 10-2023-0095892, filed on Jul. 24, 2023, and all the benefits accruing therefrom under 35 U.S.C. § 119, the content of which in its entirety is herein incorporated by reference.

### BACKGROUND

### 1. Field

The disclosure relates to a display device.

### 2. Description of the Related Art

As the information society develops, the demand for display devices for displaying images has increased and diversified. For example, display devices have been applied to various electronic devices such as smartphones, digital cameras, laptop computers, navigation devices, and smart televisions. The display devices may be flat panel display devices such as liquid crystal display devices, field emission display devices, or organic light emitting display devices. Among such flat panel display devices, a light emitting display device may display an image without a backlight unit for providing light to a display panel because each of pixels of the display panel includes light emitting elements that may emit light by themselves.

### SUMMARY

Recently, a display device may be desired to have a high pixel integration degree to be implemented with high resolution. When the display device has the high pixel integration degree, areas of emission areas in which light emitting elements are disposed are reduced, and thus, it may be difficult to implement light emitting elements to be separated from each other for each emission area through a mask process.

Embodiments of the disclosure provide a display device capable of forming light emitting elements separated from each other for each emission area without a mask process.

Embodiments of the disclosure also provide a display device of which reliability of a display panel is improved by preventing permeation of moisture and oxygen through a bank structure during a manufacturing process.

However, Embodiments of the disclosure are not restricted to those set forth herein. The above and other aspects of the disclosure will become more apparent to one of ordinary skill in the art to which the disclosure pertains by referencing the detailed description of the disclosure given below.

In an embodiment of the disclosure, a display device includes a substrate including an emission area and a non-emission area; an anode electrode positioned on the emission area of the substrate; a pixel defining layer positioned on the anode electrode and overlapping the non-emission area, where a first opening is defined through the pixel defining layer; a first bank structure positioned on the pixel defining layer, and including at least two different conductive materials, where a second opening is defined through the first bank structure; a second bank structure positioned on the first bank structure and including at least two different materials; and a first encapsulation layer positioned on the second bank structure, where the first bank structure includes a first bank layer and a second bank layer including a first tip protruding toward a center of the first opening more than a side surface of the first bank layer is, the second bank structure includes a third bank layer and a fourth bank layer including a second tip protruding toward a center of the second opening more than a side surface of the third bank layer is, and the first encapsulation layer covers the first tip and the second tip.

In an embodiment, a display device may further include a first light emitting layer positioned on the anode electrode to overlap the first opening; a cathode electrode positioned on the first light emitting layer; a first organic pattern positioned on the second bank layer while surrounding the first opening, and including a same material as the first light emitting layer; and a first electrode pattern positioned on the first organic pattern while surrounding the first opening, and including a same material as the cathode electrode.

In an embodiment, the first light emitting layer and the cathode electrode may be in contact with the side surface of the first bank layer.

In an embodiment, the first organic pattern may be spaced apart from the first light emitting layer, and the first electrode pattern may be spaced apart from the cathode electrode, and the first organic pattern and the first electrode pattern may overlap the first tip.

In an embodiment, the first bank layer may include aluminum, and the second bank layer includes titanium.

In an embodiment, the first encapsulation layer may be in contact with the side surface of the first bank layer and the first tip of the second bank layer.

In an embodiment, the second bank layer may include a first surface opposite to the third bank layer, and the first surface may include a first portion, with which the first organic pattern is in contact; a second portion, with which the first encapsulation layer is in contact; and a third portion, with which the third bank layer may be in contact.

In an embodiment, the second portion may be positioned between the first portion and the third portion, and the first portion, the second portion, and the third portion are integrally formed as a single unitary and indivisible part.

In an embodiment, the first encapsulation layer may be in contact with the side surface of the third bank layer.

In an embodiment, a cavity may be defined between the fourth bank layer and the first encapsulation layer to overlap the second tip.

In an embodiment, a display device may further include a second encapsulation layer positioned on the first encapsulation layer, where the cavity may be filled with the second encapsulation layer.

In an embodiment, a space completely surrounded by the first encapsulation layer may be defined between the second bank layer and the fourth bank layer in a direction perpendicular to the substrate.

In an embodiment, the third bank layer may include an inorganic film including about 33% or greater of oxygen, the fourth bank layer includes an inorganic film including about 33% or greater of nitrogen.

In an embodiment, the third bank layer may include an organic material or an inorganic material, and the fourth bank layer may include an organic material.

In an embodiment, a width of the third bank layer may be less than a width of the fourth bank layer.

In an embodiment, the first bank layer and the second bank layer may overlap the emission area, and the third bank layer, and the fourth bank layer may not overlap the emission area.

In an embodiment of the disclosure, a display device includes a substrate including a first emission area, a second emission area, and a non-emission area positioned between the first emission area and the second emission area; a first anode electrode positioned on the first emission area of the substrate; a second anode electrode positioned on the second emission area of the substrate; a pixel defining layer positioned on the non-emission area of the substrate between the first anode electrode and the second anode electrode, where openings are defined through the pixel defining layer; a first bank structure positioned on the pixel defining layer and including at least two different conductive materials; a second bank structure positioned on the first bank structure and including different inorganic films; and a first encapsulation layer positioned on the second bank structure, where the first bank structure includes a first bank layer and a second bank layer including first tips, each protruding toward a center of a corresponding one of the openings more than a corresponding one of side surfaces of the first bank layer is, the second bank structure includes a third bank layer and a fourth bank layer including second tips, each protruding to toward a center of a corresponding one of the openings more than a corresponding one of side surfaces of the third bank layer is, and the first encapsulation layer covers the first tips and the second tips.

In an embodiment, the first encapsulation layer may include a first inorganic layer overlapping the first emission area; and a second inorganic layer overlapping the second emission area, and a portion of the first inorganic layer overlapping the fourth bank layer and a portion of the second inorganic layer overlapping the fourth bank layer may be spaced apart from each other.

In an embodiment, a display device may further include a first light emitting layer positioned on the first anode electrode; a second light emitting layer positioned on the second anode electrode; a first organic pattern positioned on the second bank layer to overlap the first emission area, including a same material as the first light emitting layer, and spaced apart from the first light emitting layer; and a second organic pattern positioned on the second bank layer to overlap the second emission area, including a same material as the second light emitting layer, and spaced apart from the second light emitting layer, where the third bank layer may be positioned between the first organic pattern and the second organic pattern.

In an embodiment, a display device may further include a first light emitting element including the first anode electrode and the first light emitting layer; and a second light emitting element including the second anode electrode and the second light emitting layer, where in a plan view, the first light emitting element and the second light emitting element are completely surrounded by the pixel defining layer, and in the plan view, the pixel defining layer may be completely surrounded by the first bank structure.

In a display device according to embodiments of the disclosure, the display device includes a first bank structure, and it is thus possible to form light emitting elements separated from each other for each emission area without using a mask process. In such embodiments, the display device includes a second bank structure disposed on the first bank structure, and it is thus possible to prevent permeation of moisture introduced through the first bank structure. Accordingly, the display device may be formed with high resolution, and reliability of the display device against the permeation of the moisture may be improved.

The effects of the disclosure are not limited to the aforementioned effects, and various other effects are included in the specification.

### BRIEF DESCRIPTION OF THE DRAWINGS

The above and other features of embodiments of the disclosure will become more apparent by describing in detail embodiments thereof with reference to the attached drawings, in which:

FIG. 1 is a perspective view illustrating a display device according to an embodiment;

FIG. 2 is a schematic cross-sectional view of the display device of FIG. 1;

FIG. 3 is a cross-sectional view of the display device in FIG. 2 in which a bending area is bent;

FIG. 4 is a plan view illustrating an arrangement of emission areas in a display area of a display device according to an embodiment;

FIG. 5 is a cross-sectional view of the display device taken along line X1-X1′ of FIG. 4;

FIG. 6 is an enlarged cross-sectional view of the portion ‘T1’ of FIG. 5;

FIG. 7 is an enlarged cross-sectional view of the portion ‘T3’ of FIG. 6;

FIG. 8 is an enlarged cross-sectional view of the portion ‘T5’ of FIG. 7;

FIG. 9 is an enlarged cross-sectional view of the portion ‘T5’ of FIG. 7 according to another embodiment;

FIG. 10 is an enlarged cross-sectional view of the portion ‘T1’ of FIG. 5 according to another embodiment;

FIG. 11 is an enlarged cross-sectional view of the portion ‘Q5’ of FIG. 10; and

FIG. 12 is an enlarged cross-sectional view of the portion ‘Q5’ of FIG. 10 according to another embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within +30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments will be described in detail with reference to the accompanying drawings.

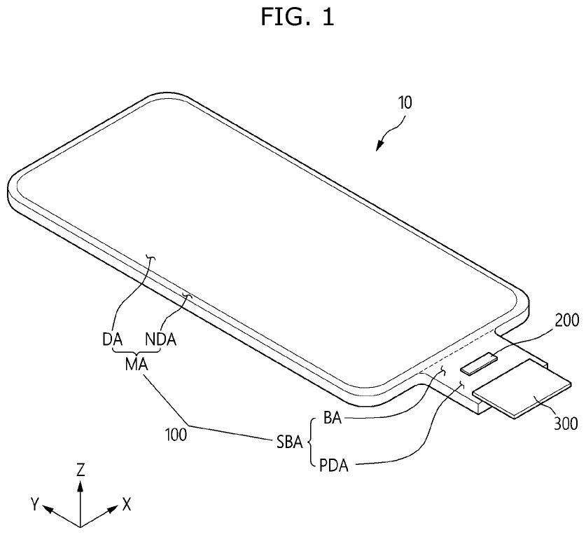

FIG. 1 is a perspective view illustrating a display device according to an embodiment.

Referring to FIG. 1, a display device 10 according to an embodiment may be included in an electronic device to provide a screen displayed on the electronic device. The electronic device may refer to any electronic device that provides a display screen, for example, televisions, laptop computers, monitors, billboards, the Internet of Things (IoT), mobile phones, smartphones, tablet personal computers (PCs), electronic watches, smart watches, watch phones, head mounted displays, mobile communication terminals, electronic notebooks, electronic books, portable multimedia players (PMPs), navigation devices, game machines, digital cameras, camcorders, or the like.

A shape of the display device 10 may be variously modified. For example, the display device 10 may have a rectangular shape, in a plan view (or when viewed in a third direction (Z-axis direction), having short sides in a first direction (X-axis direction) and long sides in a second direction (Y-axis direction) crossing the first direction. A corner where the short side in the first direction (X-axis direction) and the long side in the second direction (Y-axis direction) meet may be rounded with a curvature, but is not limited thereto, and may also be right-angled. Here, the third direction (Z-axis direction) may be a thickness direction of the display device 10. The shape of the display device 10 in a plan view is not limited to the rectangular shape, and may be a shape similar to other polygonal shapes, a circular shape, or an elliptical shape.

The display device 10 may include a display panel 100, a display driver 200, and a circuit board 300.

The display panel 100 may include a main area MA and a sub-area SBA.

The main area MA may include a display area DA including pixels for displaying an image and a non-display area NDA disposed around the display area DA. The display area DA may emit light from a plurality of emission areas. In an embodiment, for example, the display panel 100 may include pixel circuits, a pixel defining layer defining the emission areas, and self-light emitting elements.

In an embodiment, for example, the self-light emitting element may include at least one selected from an organic light emitting diode (LED) including an organic light emitting layer, a quantum dot LED including a quantum dot light emitting layer, an inorganic LED including an inorganic semiconductor, and a micro LED, but is not limited thereto.

A plurality of pixels, a plurality of scan lines, a plurality of data lines, and a plurality of power lines may be disposed in the display area DA. Each of the plurality of pixels may be defined as a minimum unit emitting light, and each of the self-light emitting elements described above may be each of the pixels. The plurality of scan lines may supply scan signals received from a scan driver to the plurality of pixels. The plurality of data lines may supply data voltages received from the display driver 200 to the plurality of pixels. The plurality of power lines may supply source voltages received from the display driver 200 to the plurality of pixels.

The non-display area NDA may be an area outside the display area DA. The non-display area NDA may be defined as an edge area of the main area MA of the display panel 100. The non-display area NDA may include the scan driver for supplying the scan signals to the scan lines, and fan-out lines connecting the display driver 200 and the display area DA to each other.

The sub-area SBA may be an area extending from one side of the main area MA. The sub-area SBA may include a bending area BA and a pad area PDA.

The bending area BA may be disposed between the main area MA and the pad area PA in the second direction (Y-axis direction). The bending area BA may extend in the first direction (X-axis direction). The bending area BA may be an area bent below the display panel 100.

The pad area PDA may be a lower edge area of the display panel 100. The pad area PDA may include the display driver 200, display pads, and the circuit board 300.

The display drivers 200 may be disposed in the pad area PDA. Each of the display drivers 200 may be attached to the non-display area NDA of the display panel 100 in a chip on glass (COG) manner. In another embodiment, each of the display drivers 200 may also be attached to the circuit board 300 in a chip on plastic (COP) manner.

The circuit boards 300 may be attached onto the display pads using a conductive adhesive member such as an anisotropic conductive film and an anisotropic conductive adhesive. Accordingly, the circuit boards 300 may be electrically connected to signal lines of the display panel 100. Each of the circuit boards 300 may be a flexible printed circuit board or a flexible film such as a chip on film.

Although not illustrated in the drawings, a plurality of display pads may be disposed at one end of the pad area PDA, and may be in contact with the circuit board 300. The display pads may be connected to a graphic system through the circuit board 300. The plurality of display pads may be connected to the circuit board 300 to receive digital video data, and may supply the digital video data to the display driver 200.

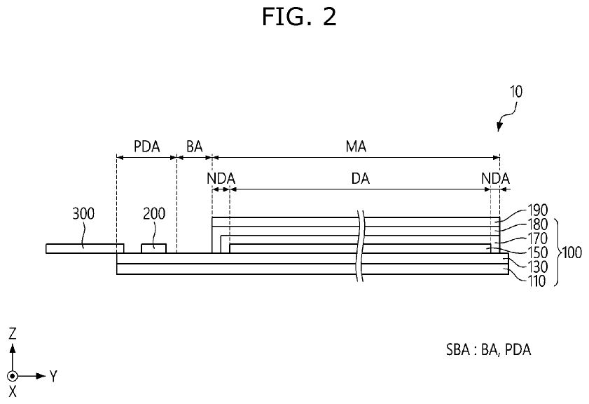

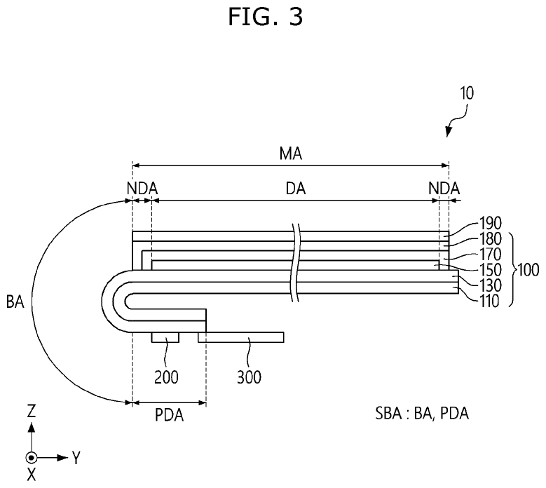

FIG. 2 is a cross-sectional view of the display device 10 of FIG. 1 viewed from a side. FIG. 3 is a cross-sectional view of the display device in FIG. 2 in which a bending area is bent.

Referring to FIG. 2, an embodiment of the display device 10 may include a display panel 100, a color filter layer 190, a display driver 200, and a circuit board 300. The display panel 100 may include a substrate 110, a thin film transistor layer 130, a display element layer 150, a thin film encapsulation layer 170, and a touch sensor layer 180.

The substrate 110 may be a base substrate or a base member. The substrate 110 may be a flexible substrate that may be bent, folded, and rolled. In an embodiment, for example, the substrate 110 may include a polymer resin such as polyimide (PI), but is not limited thereto. In another embodiment, for example, the substrate 110 may include a glass material or a metal material.

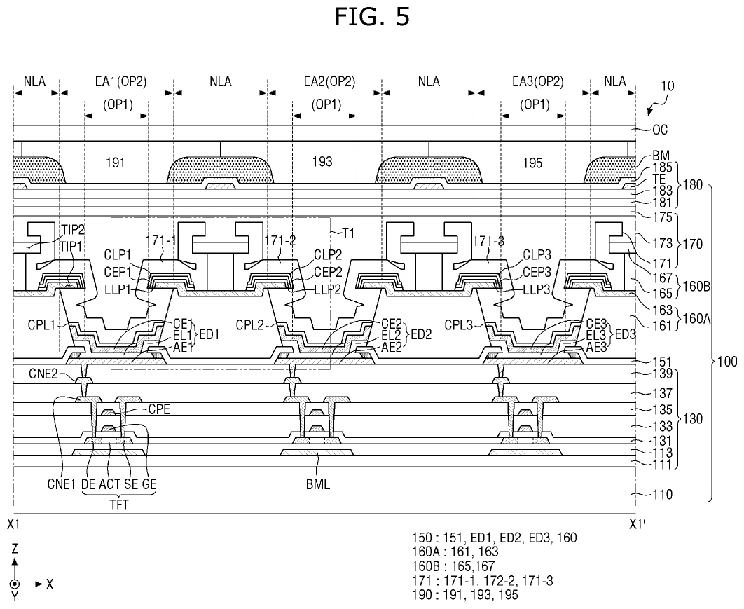

The thin film transistor layer 130 may be disposed on the substrate 110. The thin film transistor layer 130 may include a plurality of thin film transistors TFT (see FIG. 5). The thin film transistor layer 130 may be disposed in the main area MA, the bending area BA, and the pad area PDA. The thin film transistors, gate lines, data lines, and power lines of the thin film transistor layer 130 may be disposed in the display area DA of the main area MA, and gate control lines and fan-out lines of the thin film transistor layer 130 may be disposed in the non-display area NDA of the main area MA. In addition, lead lines of the thin film transistor layer 130 may be disposed in the bending area BA and the pad area PDA.

The display element layer 150 may be disposed on the thin film transistor layer 130. The display element layer 150 may include a plurality of light emitting elements, each including an anode electrode, a light emitting layer, and a cathode electrode to emit light, a pixel defining layer, a bank structure, or the like.

In an embodiment, the light emitting layer may be an organic light emitting layer including an organic material. The light emitting layer may include a hole transporting layer, an organic light emitting layer, and an electron transporting layer. When the anode electrode receives a voltage through the thin film transistor of the thin film transistor layer 130 and the cathode electrode receives a cathode voltage, holes and electrons may move to the organic light emitting layer through the hole transporting layer and the electron transporting layer, respectively, and may be combined with each other in the organic light emitting layer to emit light. In another embodiment, the light emitting element may include a quantum dot light emitting diode including a quantum dot light emitting layer, an inorganic light emitting diode including an inorganic semiconductor, or a micro light emitting diode.

The thin film encapsulation layer 170 may cover an upper surface and side surfaces of the display element layer 150, and may protect the display element layer 150. The thin film encapsulation layer 170 may include at least one inorganic film and at least one organic film for encapsulating the display element layer 150.

The touch sensor layer 180 may be disposed on the thin film encapsulation layer 170. The touch sensor layer 180 may include a plurality of touch electrodes for sensing a user's touch in a capacitance manner and a plurality of touch lines. In an embodiment, for example, the touch sensor layer 180 may sense the user's touch in a mutual capacitance manner or a self-capacitance manner. The plurality of touch electrodes of the touch sensor layer 180 may be disposed in a touch sensor area overlapping the display area DA. The touch lines of the touch sensor layer 180 may be disposed in a touch peripheral area overlapping the non-display area NDA.

The e 190 may be disposed on the touch sensor layer 180. The color filter layer 190 may include a plurality of color filters each corresponding to the plurality of emission areas. Each of the color filters may selectively transmit light of a specific wavelength therethrough and block or absorb light of other wavelengths. The color filter layer 190 may absorb some of light introduced from the outside of the display device 10 to reduce reflected light by external light. Accordingly, the color filter layer 190 may prevent distortion of colors due to external light reflection.

Since the color filter layer 190 is directly disposed on the touch sensor layer 180, the display device 10 may not include a separate substrate for the color filter layer 190.

Referring to FIG. 3, the pad area PDA of the display device 10 may be bent by the bending area BA. When the pad area PDA is bent by the bending area BA, the display driver 200 and the circuit board 300 disposed or positioned in the pad area PDA may overlap the main area MA in the third direction (Z-axis direction).

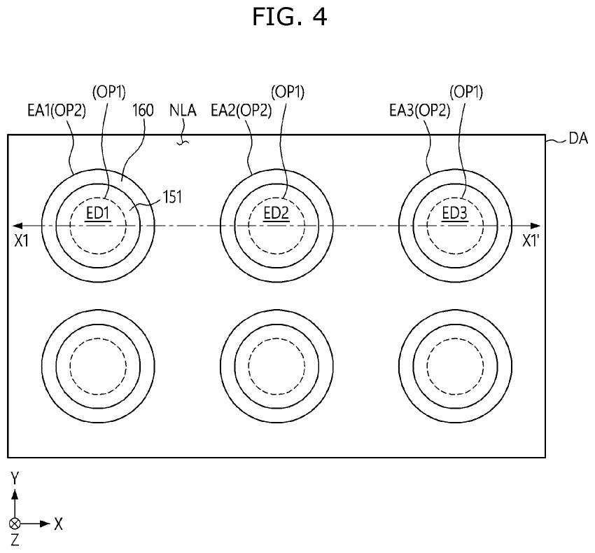

FIG. 4 is a plan view illustrating an arrangement of emission areas EA1, EA2, and EA3 in a display area DA a display device according to an embodiment.

Referring to FIG. 4, in an embodiment, the display area DA may include a plurality of emission areas EA1, EA2, and EA3 and a non-emission area NLA. The non-emission area NLA may be defined or positioned while surrounding the emission areas EA1, EA2, and EA3. An inorganic pixel defining layer 151, a bank structure 160, and a light blocking layer BM may be disposed or positioned in the non-emission area NLA.

The emission areas EA1, EA2, and EA3 may include first emission areas EA1, second emission areas EA2, and third emission areas EA3 that emit light of different colors, respectively. The plurality of emission areas EA1, EA2, and EA3 may emit red, green, or blue light, respectively, and colors of the light emitted from the respective emission areas EA1, EA2, and EA3 may be different from each other depending on types of light emitting elements ED1, ED2, and ED3. In an embodiment, the first emission area EA1 may emit first light, which is the red light, the second emission area EA2 may emit second light, which is the green light, and the third emission area EA3 may emit third light, which is the blue light. However, the disclosure is not limited thereto.

In a plan view (or when viewed in the third direction or Z-axis direction), the light emitting elements ED1, ED2, and ED3 overlapping the respective emission areas EA1, EA2, and EA3 may be surrounded by the inorganic pixel defining layer 151 defining first openings OP1. In addition, the inorganic pixel defining layer 151 may be surrounded by the bank structure 160. The bank structure 160 may define second openings OP2. In other words, the light emitting elements ED1, ED2, and ED3 overlapping the respective emission areas EA1, EA2, and EA3 may be disposed or positioned within the first openings OP1 and the second openings OP2.

FIG. 5 is a cross-sectional view of the display device 10 taken along line X1-X1′ of FIG. 4.

Referring to FIG. 5, an embodiment of the display panel 100 may include the substrate 110, the thin film transistor layer 130, the display element layer 150, the thin film encapsulation layer 170, and the touch sensor layer 180.

The substrate 110 is substantially the same as that described above, and any repetitive detailed description thereof will be omitted.

The thin film transistor layer 130 may include a first buffer layer 111, a bottom metal layer BML, a second buffer layer 113, thin film transistors TFT, a gate insulating layer 131, a first interlayer insulating layer 133, capacitor electrodes CPE, a second interlayer insulating layer 135, first connection electrodes CNE1, a first passivation layer 137, second connection electrodes CNE2, and a second passivation layer 139.

The first buffer layer 111 may be disposed on the substrate 110. The first buffer layer 111 may include an inorganic film capable of preventing permeation of air or moisture. In an embodiment, for example, the first buffer layer 111 may include a plurality of inorganic films that are alternately stacked.

The bottom metal layer BML may be disposed on the first buffer layer 111. In an embodiment, for example, the bottom metal layer BML may be formed as a single layer or multiple layers, where each layer herein includes or be made of at least one selected from molybdenum (Mo), aluminum (Al), chromium (Cr), gold (Au), titanium (Ti), nickel (Ni), neodymium (Nd), and copper (Cu), or a combination (e.g., an alloy) thereof.

The second buffer layer 113 may cover the first buffer layer 111 and the bottom metal layer BML. The second buffer layer 113 may include an inorganic film capable of preventing permeation of air or moisture. In an embodiment, for example, the second buffer layer 113 may include a plurality of inorganic films that are alternately stacked.

The thin film transistor TFT may be disposed on the second buffer layer 113. The thin film transistor TFT may constitute a pixel circuit of each of the plurality of pixels. In an embodiment, for example, the thin film transistor TFT may be a driving transistor or a switching transistor of the pixel circuit. The thin film transistor TFT may include a semiconductor layer ACT, a source electrode SE, a drain electrode DE, and a gate electrode GE.

The semiconductor layer ACT may be disposed on the second buffer layer 113. The semiconductor layer ACT may overlap the bottom metal layer BML and the gate electrode GE in the third direction (Z-axis direction), and may be insulated from the gate electrode GE by the gate insulating layer 131. A material of the semiconductor layer ACT in portions of the semiconductor layer ACT may become conductors to form the source electrode SE and the drain electrode DE.

The gate electrode GE may be disposed on the gate insulating layer 131. The gate electrode GE may overlap the semiconductor layer ACT with the gate insulating layer 131 interposed therebetween.

The gate insulating layer 131 may be disposed on the semiconductor layer ACT. For example, the gate insulating layer 131 may cover the semiconductor layer ACT and the second buffer layer 113, and may insulate the semiconductor layer ACT and the gate electrode GE from each other. The gate insulating layer 131 may be provided with contact holes through which the first connection electrodes CNE1 extend.

The first interlayer insulating layer 133 may cover the gate electrodes GE and the gate insulating layer 131. The first interlayer insulating layer 133 may be provided with contact holes through which the first connection electrodes CNE1 extend. The contact holes of the first interlayer insulating layer 133 may be connected to the contact holes of the gate insulating layer 131 and contact holes of the second interlayer insulating layer 135.

The capacitor electrodes CPE may be disposed on the first interlayer insulating layer 133. The capacitor electrode CPE may overlap the gate electrode GE in a thickness direction or the third direction (Z-axis direction). The capacitor electrode CPE and the gate electrode GE may form capacitance.

The second interlayer insulating layer 135 may cover the capacitor electrodes CPE and the first interlayer insulating layer 133. The second interlayer insulating layer 135 may be provided with contact holes through which the first connection electrodes CNE1 extend. The contact holes of the second interlayer insulating layer 135 may be connected to the contact holes of the first interlayer insulating layer 133 and the contact holes of the gate insulating layer 131.

The first connection electrodes CNE1 may be disposed on the second interlayer insulating layer 135. The first connection electrode CNE1 may electrically connect the drain electrode DE of the thin film transistor TFT and the second connection electrode CNE2 to each other. The first connection electrode CNE1 may be inserted into the contact holes formed in the second interlayer insulating layer 135, the first interlayer insulating layer 133, and the gate insulating layer 131 to be in contact with the drain electrode DE of the thin film transistor TFT.

The first passivation layer 137 may cover the first connection electrodes CNE1 and the second interlayer insulating layer 135. The first passivation layer 137 may protect the thin film transistors TFT. The first passivation layer 137 may be provided with contact holes through which the second connection electrodes CNE2 extend.

The second connection electrodes CNE2 may be disposed on the first passivation layer 137. The second connection electrodes CNE2 may electrically connect the first connection electrodes CNE1 and anode electrodes AE1, AE2, and AE3 of light emitting elements ED1, ED2, and ED3 to each other. The second connection electrode CNE2 may be inserted into the contact hole formed in the first passivation layer 137 to be in contact with the first connection electrode CNE1.

The second passivation layer 139 may cover the second connection electrodes CNE2 and the first passivation layer 137. The second passivation layer 139 may be provided with contact holes through which the anode electrodes AE1, AE2, and AE3 of the light emitting elements ED1, ED2, and ED3 extend.

The display element layer 150 may be disposed on the thin film transistor layer 130. The display element layer 150 may include the light emitting elements ED1, ED2, and ED3, the inorganic pixel defining layer 151, and the bank structure 160.

The light emitting elements ED1, ED2, and ED3 may be disposed on the second passivation layer 139. The light emitting elements ED1, ED2, and ED3 may include the anode electrodes AE1, AE2, and AE3, light emitting layers EL1, EL2, and EL3, and cathode electrodes CE1, CE2, and CE3, respectively.

The anode electrodes AE1, AE2, and AE3 may be disposed in the plurality of emission areas EA1, EA2, and EA3, respectively. The anode electrodes AE1, AE2, and AE3 may include a first anode electrode AE1 disposed in the first emission area EA1, a second anode electrode AE2 disposed in the second emission area EA2, and a third anode electrode AE3 disposed in the third emission area EA3. The anode electrodes AE1, AE2, and AE3 may be disposed to be spaced apart from each other on the second passivation layer 139. The anode electrodes AE1, AE2, and AE3 may be disposed in different emission areas EA1, EA2, and EA3, respectively, to constitute the light emitting elements ED1, ED2, and ED3 emitting the light of the different colors, respectively.

The anode electrodes AE1, AE2, and AE3 may be electrically connected to the drain electrodes DE of the thin film transistors TFT through the first and second connection electrodes CNE1 and CNE2. The anode electrodes AE1, AE2, and AE3 may include or be made of a metal having high electrical conductivity. In an embodiment, for example, the anode electrodes AE1, AE2, and AE3 may have a stacked film structure in which a layer including or made of a material having a high work function, such indium tin oxide (ITO), indium zinc oxide (IZO), zinc oxide (ZnO), or indium oxide (In₂O₃) and a layer made of a reflective material such as silver (Ag), magnesium (Mg), aluminum (Al), platinum (Pt), lead (Pb), palladium (Pd), gold (Au), nickel (Ni), neodymium (Nd), iridium (Ir), chromium (Cr), lithium (Li), calcium (Ca), or mixtures thereof are stacked. The layer including or made of the material having the high work function may be disposed at a layer above the layer made of the reflective material, and be thus disposed close to the light emitting layers EL1, EL2, and EL3. In an embodiment, for example, the anode electrodes AE1, AE2, and AE3 may have a multilayer structure of ITO/Mg, ITO/MgF, ITO/Ag, and ITO/Ag/ITO, but are not limited thereto.

The inorganic pixel defining layer 151 may be disposed or positioned on the second passivation layer 139 and the anode electrodes AE1, AE2, and AE3. The inorganic pixel defining layer 151 may define a plurality of first openings OP1 overlapping the emission areas EA1, EA2, and EA3. The inorganic pixel defining layer 151 may be entirely disposed on the second passivation layer 139 to overlap the non-emission area NLA, and may overlap the emission areas EA1, EA2, and EA3 to partially overlap the anode electrodes AE1, AE2, and AE3. The inorganic pixel defining layer 151 may expose portions of upper surfaces of the anode electrodes AE1, AE2, and AE3 overlapping the first openings OP1.

The inorganic pixel defining layer 151 may include an inorganic insulating material. In an embodiment, for example, the inorganic pixel defining layer 151 may include aluminum oxide (Al₂O₃), titanium oxide (TiO₂), tantalum oxide (Ta₂O₅), hafnium oxide (HfO₂), zinc oxide (ZnO), silicon oxide (SiO₂), silicon nitride (Si₃N₄), or silicon oxynitride (SiON).

Residual patterns 157 may be disposed or positioned between the inorganic pixel defining layer 151 and the anode electrodes AE1, AE2, and AE3. Detailed features thereof will be described later.

The bank structure 160 may be disposed or positioned in the non-emission area NLA, and may be disposed or positioned on the inorganic pixel defining layer 151. The bank structure 160 may include a first bank structure 160A and a second bank structure 160B.

The first bank structure 160A may be disposed or positioned on the inorganic pixel defining layer 151. The first bank structure 160A may help the display device 10 to individually form the light emitting elements ED1, ED2, and ED3 to overlap the respective emission areas EA1, EA2, and EA3. In addition, the first bank structure 160A may define the second openings OP2 defining the emission areas EA1, EA2, and EA3. The second openings OP2 may overlap the first openings OP1, and may have a greater width than the first openings OP1. In other words, the first openings OP1 may be positioned within the second openings OP2.

The first bank structure 160A may include a first bank layer 161 and a second bank layer 163 that include different conductive materials from each other and perform different roles, respectively.

The first bank layer 161 may be disposed or positioned on the inorganic pixel defining layer 151. The first bank layer 161 may include a metal having high electrical conductivity. As an example, the first bank layer 161 may include aluminum (Al). In the display device 10 according to an embodiment, the cathode electrodes CE1, CE2, and CE3 disposed in the different emission areas EA1, EA2, and EA3 are not directly connected to each other, and may be electrically connected to each other through the first bank layer 161. Accordingly, the cathode electrodes CE1, CE2, and CE3 disposed in the different emission areas EA1, EA2, and EA3 may be spaced apart from each other with the first bank layer 161 interposed therebetween, and may be in contact with the first bank layer 161.

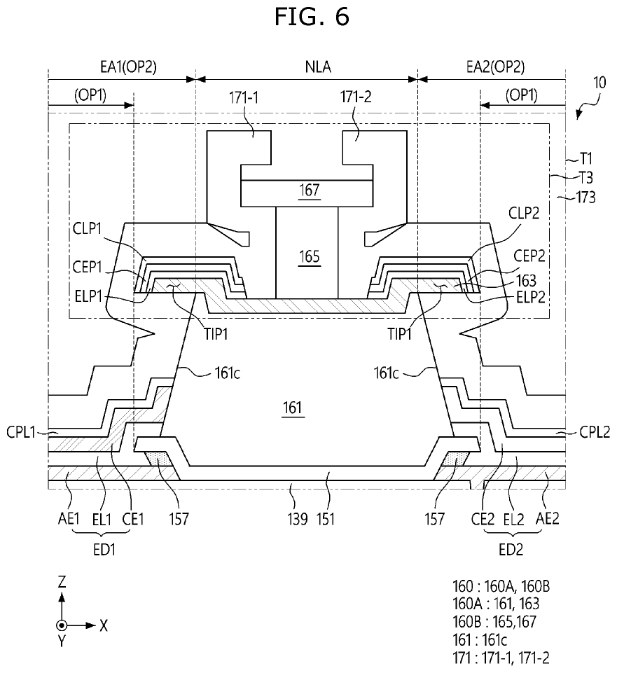

The second bank layer 163 may be disposed or positioned on the first bank layer 161. The second bank layer 163 may include a material having an etch rate lower than that of the first bank layer 161. In an embodiment, for example, the second bank layer 163 may include titanium (Ti). The second bank layer 163 may have a shape in which it protrudes more than both side surfaces 161c (see FIG. 6) of the first bank layer 161 toward the first openings OP1. Accordingly, the second bank layer 163 may include tips TIP1 protruding toward the first openings OP1. Accordingly, undercut structures may be defined or formed between lower portions of the protruding tips TIP1 of the second bank layer 163 and the first bank layer 161. In the display device 10 according to an embodiment, the second bank layer 163 includes the protruding tips TIP1, and accordingly, the light emitting elements ED1, ED2, and ED3 may be individually formed in the respective emission areas EA1, EA2, and EA3.

The second bank structure 160B may be disposed or positioned on the first bank structure 160A to overlap the non-emission area NLA. The second bank structure 160B may block a permeation path of oxygen and moisture introduced through the first bank structure 160A. The second bank structure 160B may include a third bank layer 165 and a fourth bank layer 167 that include different materials from each other and perform different roles, respectively.

The third bank layer 165 may be disposed or positioned on the second bank layer 163. The third bank layers 165 may overlap the non-emission area NLA and be positioned between a plurality of patterns ELP, CEP, and CLP to be described later to be spaced apart from each other. The third bank layer 165 may be an inorganic film. Accordingly, the third bank layer 165 may block moisture and oxygen that may permeate into an upper surface of the second bank layer 163.

The fourth bank layer 167 may be disposed or positioned on the third bank layer 165. The fourth bank layer 167 may include tips TIP2 protruding from sides more toward a center of the first openings OP1 than the third bank layer 165. Accordingly, undercut structures may be formed between lower portions of the protruding tips TIP2 of the fourth bank layer 167 and the third bank layer 165. The fourth bank layer 167 may include an inorganic film having an etch rate lower than that of the third bank layer 165. Detailed features thereof will be described later.

The light emitting layers EL1, EL2, and EL3 may be disposed on the anode electrodes AE1, AE2, and AE3, respectively. The light emitting layers EL1, EL2, and EL3 may be formed after the bank structure 160 is formed in a manufacturing process. The light emitting layers EL1, EL2, and EL3 may be organic light emitting layers including or made of an organic material, and may be formed on the anode electrodes AE1, AE2, and AE3, respectively, through a deposition process. When the thin film transistors TFT apply predetermined anode voltages to the anode electrodes AE1, AE2, and AE3 and the cathode electrodes CE1, CE2, and CE3 receives cathode voltages, holes and electrons may move to the light emitting layers EL1, EL2, and EL3 through hole transporting layers and electron transporting layers, respectively, and may be combined with each other in the light emitting layers EL1, EL2, and EL3 to emit light.

The light emitting layers EL1, EL2, and EL3 may include a first light emitting layer EL1, a second light emitting layer EL2, and a third light emitting layer EL3 disposed in the different emission areas EA1, EA2, and EA3, respectively. The first light emitting layer EL1 may be disposed on the first anode electrode AE1 in the first emission area EA1, the second light emitting layer EL2 may be disposed on the second anode electrode AE2 in the second emission area EA2, and the third light emitting layer EL3 may be disposed on the third anode electrode AE3 in the third emission area EA3. In an embodiment, for example, the first light emitting layer EL1 may be a light emitting layer that emits the red light, which is light of a first color, the second light emitting layer EL2 may be a light emitting layer that emits the green light, which is light of a second color, and the third light emitting layer EL3 may be a light emitting layer that emits the blue light, which is light of a third color.

The cathode electrodes CE1, CE2, and CE3 may be disposed on the light emitting layers EL1, EL2, and EL3, respectively. The cathode electrodes CE1, CE2, and CE3 may include a transparent conductive material to emit light generated from the light emitting layers EL1, EL2, and EL3. The cathode electrodes CE1, CE2, and CE3 may receive a common voltage or a low potential voltage. When the anode electrodes AE1, AE2, and AE3 receive voltages corresponding to data voltages and the cathode electrodes CE1, CE2, and CE3 receive the low potential voltage, potential differences are formed between the anode electrodes AE1, AE2, and AE3 and the cathode electrodes CE1, CE2, and CE3, such that the light emitting layers EL1, EL2, and EL3 may emit the light.

In an embodiment, for example, the cathode electrodes CE1, CE2, and CE3 may include silver (Ag), but are not limited thereto. The cathode electrodes CE1, CE2, and CE3 may include a layer made of a material having a small work function, such as Li, Ca, LiF/Ca, LiF/Al, Al, Mg, Pt, Pd, Ni, Au, Nd, Ir, Cr, BaF, Ba, or compounds or mixtures thereof (e.g., a mixture of Ag and Mg, etc.). The cathode electrode CE1, CE2, and CE3 may further include a transparent metal oxide layer disposed on the layer including or made of the material having the small work function.

As described above, in an embodiment of the display device 10, the cathode electrodes CE1, CE2, and CE3 may be individually formed in each of different areas even in a deposition process, which does not use a mask, by the tips TIP1 of the first bank structure 160A. The cathode electrodes CE1, CE2, and CE3 may include a first cathode electrode CE1, a second cathode electrode CE2, and a third cathode electrode CE3 disposed in the different emission areas EA1, EA2, and EA3, respectively. The first cathode electrode CE1 may be disposed on the first light emitting layer EL1 in the first emission area EA1, the second cathode electrode CE2 may be disposed on the second light emitting layer EL2 in the second emission area EA2, and the third cathode electrode CE3 may be disposed on the third light emitting layer EL3 in the third emission area EA3. The individually formed cathode electrodes CE1, CE2, and CE3 may be electrically connected to each other by the first bank layer 161.

In some embodiments, the first bank structure 160A includes the protruding tips TIP1, and accordingly, the light emitting layers EL1, EL2, and EL3 and the cathode electrodes CE1, CE2, and CE3 may be individually formed, but materials may not be smoothly deposited under the protruding tips TIP1. Accordingly, materials of the light emitting layers EL1, EL2, and EL3 and the cathode electrodes CE1, CE2, and CE3 may be deposited in a direction inclined with respect to an upper surface of the substrate 110 rather than the third direction (Z-axis direction) perpendicular to the upper surface of the substrate 110. Specifically, the deposition process of forming the light emitting layers EL1, EL2, and EL3 may be performed so that the materials of the light emitting layers EL1, EL2, and EL3 are deposited in a direction that is not perpendicular to the upper surfaces of the anode electrodes AE1, AE2, and AE3, for example, in a direction inclined between the first direction (X-axis direction) and the third direction (Z-axis direction).

In an embodiment, when an angle of the deposition process of forming the light emitting layers EL1, EL2, and EL3 is defined as a first angle, the deposition process of forming the light emitting layers EL1, EL2, and EL3 may be performed at an inclined angle in a range of about 45° to about 50° from the upper surfaces of the anode electrodes AE1, AE2, and AE3. That is, the first angle may be in a range of about 45° to about 50°. Accordingly, the light emitting layers EL1, EL2, and EL3 may be formed even on partial areas hidden by the protruding tips TIP1 of the bank structure 160 and the side surfaces 161c of the first bank layer 161.

In some embodiments, the deposition process of forming the cathode electrodes CE1, CE2, and CE3 may also be performed so that the materials of the cathode electrodes CE1, CE2, and CE3 are deposited in the direction that is not perpendicular to the upper surfaces of the anode electrodes AE1, AE2, and AE3, for example, in the direction inclined between the first direction (X-axis direction) and the third direction (Z-axis direction). In an embodiment, when an angle of the deposition process of forming the cathode electrodes CE1, CE2, and CE3 is defined as a second angle, the deposition process of forming the cathode electrodes CE1, CE2, and CE3 may be performed at an inclined angle in a range of about 30° or less from the upper surfaces of the anode electrodes AE1, AE2, and AE3.

In other words, the deposition process of forming the cathode electrodes CE1, CE2, and CE3 may be performed in an inclined direction relatively closer to a horizontal direction than the deposition process of forming the light emitting layers EL1, EL2, and EL3. Accordingly, the cathode electrodes CE1, CE2, and CE3 may be deposited to be in contact with the side surfaces 161c of the first bank layer 161 in a greater area than the light emitting layers EL1, EL2, and EL3. Accordingly, the deposition process of forming the cathode electrodes CE1, CE2, and CE3 may have higher step coverage characteristics than the deposition process of forming the light emitting layers EL1, EL2, and EL3. That is, the cathode electrodes CE1, CE2, and CE3 may be deposited up to a higher position on the side surfaces 161c of the first bank layer 161 than the light emitting layers EL1, EL2, and EL3.

Capping layers CPL1, CPL2, and CPL3 may be disposed on the cathode electrodes CE1, CE2, and CE3, respectively. The capping layers CPL1, CPL2, and CPL3 may include an inorganic insulating material and cover the light emitting elements ED1, ED2, and ED3, respectively. The capping layers CPL1, CPL2, and CPL3 may prevent the light emitting elements ED1, ED2, and ED3 from being damaged by external air, and may protect the cathode electrodes CE1, CE2, and CE3 so that the cathode electrodes CE1, CE2, and CE3 are not detached.

The capping layers CPL1, CPL2, and CPL3 may include a first capping layer CPL1 overlapping the first emission area EA1, a second capping layer CPL2 overlapping the second emission area EA2, and a third capping layer CPL3 overlapping the third emission area EA3.

The capping layers CPL1, CPL2, and CPL3 overlapping the respective emission areas EA1, EA2, and EA3 may completely cover the cathode electrodes CE1, CE2, and CE3, respectively. However, the disclosure is not limited thereto, and the capping layers CPL1, CPL2, and CPL3 overlapping the respective emission areas EA1, EA2, and EA3 may expose portions of the cathode electrodes CE1, CE2, and CE3, respectively.

The capping layers CPL1, CPL2, and CPL3 may include aluminum oxide (Al₂O₃), titanium oxide (TiO₂), tantalum oxide (Ta₂O₅), hafnium oxide (HfO₂), zinc oxide (ZnO), silicon oxide (SiO₂), silicon nitride (Si₃N₄), or silicon oxynitride (SiON).

Referring to FIG. 5, a plurality of organic patterns ELP1, ELP2, and ELP3, electrode patterns CEP1, CEP2, and CEP3, and capping patterns CLP1, CLP2, and CLP3 may be disposed on the second bank layer 163 to surround the first openings OP1 in a plan view. Portions of the plurality of organic patterns ELP1, ELP2, and ELP3, electrode patterns CEP1, CEP2, and CEP3, and capping patterns CLP1, CLP2, and CLP3 may be partially etched in a manufacturing process of the display device 10. Accordingly, the plurality of organic patterns ELP1, ELP2, and ELP3, electrode patterns CEP1, CEP2, and CEP3, and capping patterns CLP1, CLP2, and CLP3 may be disposed to be spaced apart from each other in portions overlapping the non-emission area NLA.

The plurality of organic patterns ELP1, ELP2, and ELP3 may be disposed or positioned on the second bank layer 163. The organic patterns ELP1, ELP2, and ELP3 may include the same materials as the light emitting layers EL1, EL2, and EL3, respectively. A first organic pattern ELP1 may include a same material as the first light emitting layer EL1 of the first light emitting element ED1, a second organic pattern ELP2 may include a same material as the second light emitting layer EL2 of the second light emitting element ED2, and a third organic pattern ELP3 may include a same material as the third light emitting layer EL3 of the third light emitting element ED3. The organic patterns ELP1, ELP2, and ELP3 may be traces formed while the deposited materials are disconnected from the light emitting layers EL1, EL2, and EL3 by the tips TIP1 of the first bank structure 160A rather than being connected to the light emitting layers EL1, EL2, and EL3.

The plurality of electrode patterns CEP1, CEP2, and CEP3 may be disposed on the plurality of organic patterns ELP1, ELP2, and ELP3, respectively. In an embodiment, for example, a first electrode pattern CEP1, a second electrode pattern CEP2, and a third electrode pattern CEP3 may be directly disposed on the first organic pattern ELP1, the second organic pattern ELP2, and the third organic pattern ELP3, respectively. An arrangement relationship between the electrode patterns CEP1, CEP2, and CEP3 and the organic patterns ELP1, ELP2, and ELP3 may be the same as an arrangement relationship between the light emitting layers EL1, EL2, and EL3 and the cathode electrodes CE1, CE2, and CE3. The electrode patterns CEP1, CEP2, and CEP3 may include the same materials as the cathode electrodes CE1, CE2, and CE3, respectively. Such electrode patterns CEP1, CEP2, and CEP3 may be traces formed while the deposited materials are disconnected from the cathode electrodes CE1, CE2, and CE3 by the tips TIP1 of the first bank structure 160A rather than being connected to the cathode electrodes CE1, CE2, and CE3.

The plurality of capping patterns CLP1, CLP2, and CLP3 may be disposed or positioned on the plurality of electrode patterns CEP1, CEP2, and CEP3, respectively. The plurality of capping patterns CLP1, CLP2, and CLP3 may include the same materials as the capping layers CPL1, CPL2, and CPL3, respectively. An arrangement relationship between the capping patterns CLP1, CLP2, and CLP3 and the plurality of electrode patterns CEP1, CEP2, and CEP3 may be the same as an arrangement relationship between the capping layers CPL1, CPL2, and CPL3 and the cathode electrodes CE1, CE2, and CE3. Such capping patterns CLP1, CLP2, and CLP3 may be traces formed while the deposited materials are disconnected from the capping layers CPL1, CPL2, and CPL3 by the tips TIP1 of the first bank structure 160A. The capping patterns CLP1, CLP2, and CLP3 may prevent lower patterns from being peeled off during the manufacturing process.

The thin film encapsulation layer 170 may be disposed on the capping layers CPL1, CPL2, and CPL3, the capping patterns CLP1, CLP2, and CLP3, and the bank structure 160, and may cover the capping layers CPL1, CPL2, and CPL3, the capping patterns CLP1, CLP2, and CLP3, and the bank structure 160. The thin film encapsulation layer 170 may include at least one inorganic film to prevent oxygen or moisture from permeating into the display element layer 150. The thin film encapsulation layer 170 may include at least one organic film to protect a lower structure from foreign substances such as dust. In an embodiment, the thin film encapsulation layer 170 may include a first encapsulation layer 171, a second encapsulation layer 173, and a third encapsulation layer 175 that are sequentially stacked. The first encapsulation layer 171 and the third encapsulation layer 175 may be inorganic encapsulation layers, and the second encapsulation layer 173 disposed between the first encapsulation layer 171 and the third encapsulation layer 175 may be an organic encapsulation layer.

Each of the first encapsulation layer 171 and the third encapsulation layer 175 may include one or more inorganic insulating materials. The inorganic insulating material may include at least one selected from aluminum oxide, titanium oxide, tantalum oxide, hafnium oxide, zinc oxide, silicon oxide, silicon nitride, and silicon oxynitride.

The second encapsulation layer 173 may include a polymer-based material. The polymer-based material may include an acrylic resin, an epoxy-based resin, polyimide, polyethylene, and the like. In an embodiment, for example, the second encapsulation layer 173 may include an acrylic resin such as polymethyl methacrylate or polyacrylic acid. The second encapsulation layer 173 may be formed by curing a monomer or applying a polymer.

The first encapsulation layer 171 may include first to third inorganic layers 171-1, 171-2, and 171-3 disposed to each correspond to the different emission areas EA1, EA2, and EA3, respectively.

The first to third inorganic layers 171-1, 171-2, and 171-3 may be disposed to cover the capping layers CPL1, CPL2, and CPL3, the capping patterns CLP1, CLP2, and CLP3, and the bank structure 160. The first to third inorganic layers 171-1, 171-2, and 171-3 may be formed through chemical vapor deposition (CVD), and may thus be formed at a uniform thickness along profiles of lower structures. In an embodiment, for example, the first to third inorganic layers 171-1, 171-2, and 171-3 may form thin films even under the undercut structures by the tips TIP1 of the first bank structure 160A and the undercut structures by the tips TIP2 of the second bank structure 160B.

In an embodiment, as illustrated in FIG. 5, the first to third inorganic layers 171-1, 171-2, and 171-3 may be formed in a same layer, but the first to third inorganic layers 171-1, 171-2, and 171-3 may be formed in different processes, respectively. In an embodiment, for example, the first inorganic layer 171-1 may be formed after the first cathode electrode CE1 is formed, the second inorganic layer 171-2 may be formed after the second cathode electrode CE2 is formed, and the third inorganic layer 171-3 may be formed after the third cathode electrode CE3 is formed.

The first to third inorganic layers 171-1, 171-2, and 171-3 may be disposed to be spaced apart from each other in portions overlapping the non-emission area NLA. Accordingly, portions of the fourth bank layer 167 included in the second bank structure 160B may be exposed. Accordingly, portions of the fourth bank layer 167 may be in contact with the second encapsulation layer 173.

The touch sensor layer 180 may be disposed on the thin film encapsulation layer 170. The touch sensor layer 180 may include a touch buffer layer 181, a touch insulating layer 183, touch electrodes TE, and a touch protection layer 185.

The touch buffer layer 181 may be disposed on the thin film encapsulation layer 170. The touch buffer layer 181 may have insulating and optical functions. The touch buffer layer 181 may include at least one inorganic film. Alternatively, the touch buffer layer 181 may be omitted. Although not illustrated in the drawings, a connection electrode electrically connecting the touch electrodes to each other may be disposed on the touch buffer layer 181. The connection electrode may be formed as a single layer including or made of molybdenum (Mo), titanium (Ti), copper (Cu), aluminum (Al), or indium tin oxide (ITO) or be formed as a stacked structure (Ti/Al/Ti) of aluminum and titanium, a stacked structure (ITO/AI/ITO) of aluminum and ITO, an Ag—Pd—Cu (APC) alloy, and a stacked structure (ITO/APC/ITO) of an APC alloy and ITO.

The touch insulating layer 183 may cover the touch buffer layer 181. The touch insulating layer 183 may have an insulating function. In an embodiment, for example, the touch insulating layer 183 may be an inorganic film including at least one selected from a silicon nitride layer, a silicon oxynitride layer, a silicon oxide layer, a titanium oxide layer, and an aluminum oxide layer.

The touch electrodes TE may be disposed on the touch insulating layer 183 to overlap the non-emission area NLA. Each of the touch electrodes TE may not overlap the first to third emission areas EA1, EA2, and EA3. Each of the touch electrodes TE may be formed as a single layer including or made of molybdenum (Mo), titanium (Ti), copper (Cu), aluminum (Al), or indium tin oxide (ITO) or be formed as a stacked structure (Ti/Al/Ti) of aluminum and titanium, a stacked structure (ITO/Al/ITO) of aluminum and ITO, an APC alloy, and a stacked structure (ITO/APC/ITO) of an APC alloy and ITO.

The touch protection layer 185 may cover the touch electrodes TE and the touch insulating layer 183. The touch protection layer 185 may have insulating and optical functions. The touch protection layer 185 may include or be made of the material listed above with respect to the touch insulating layer 183.

The light blocking layer BM may be disposed or positioned in the non-emission area NLA, and may be disposed on the touch sensor layer 180. The light blocking layer BM may be disposed to overlap the inorganic pixel defining layer 151, the bank structure 160, and the touch electrodes TE. The light blocking layer BM may include a light absorbing material. For example, the light blocking layer BM may include an inorganic black pigment or an organic black pigment. The inorganic black pigment may be carbon black, and the organic black pigment may include at least one of lactam black, perylene black, and aniline black, but the disclosure is not limited thereto. The light blocking layer BM may prevent color mixing due to permeation of visible light between the first to third emission areas EA1, EA2, and EA3 to improve a color gamut of the display device 10.

The color filter layer 190 may be disposed on each of the touch protection layer 185 and the light blocking layer BM to overlap the emission areas EA1, EA2, and EA3.

The color filter layer 190 may include a first color filter 191, a second color filter 192, and a third color filter 193 disposed to each correspond to the different emission areas EA1, EA2, and EA3. A plurality of color filters 191, 193, and 195 may include colorants such as dyes or pigments absorbing light of wavelength bands other than light of a specific wavelength band, and may be disposed to correspond to the colors of the light emitting from the emission areas EA1, EA2, and EA3. In an embodiment, for example, the first color filter 191 may be a red color filter disposed to overlap the first emission area EA1 and transmitting only the first light, which is the red light, therethrough. The second color filter 193 may be a green color filter disposed to overlap the second emission area EA2 and transmitting only the second light, which is the green light, therethrough, and the third color filter 195 may be a blue color filter disposed to overlap the third emission area EA3 and transmitting only the third light, which is the blue light, therethrough.

A structure in which the plurality of color filters 191, 193, and 195 do not overlap other adjacent color filters 191, 193, and 195 on the light blocking layer BM has been illustrated in FIG. 5, but the disclosure is not limited thereto. In other words, the plurality of color filters 191, 193, and 195 may be disposed to partially overlap other adjacent color filters 191, 193, and 195.

An overcoat layer OC may be disposed on the color filter layer 190 and the light blocking layer BM to planarize upper ends of the plurality of color filters 191, 193, and 195. The overcoat layer OC may be a colorless light transmitting layer that does not have a color of a visible light band. In an embodiment, for example, the overcoat layer OC may include a colorless light transmitting organic material such as an acrylic resin.

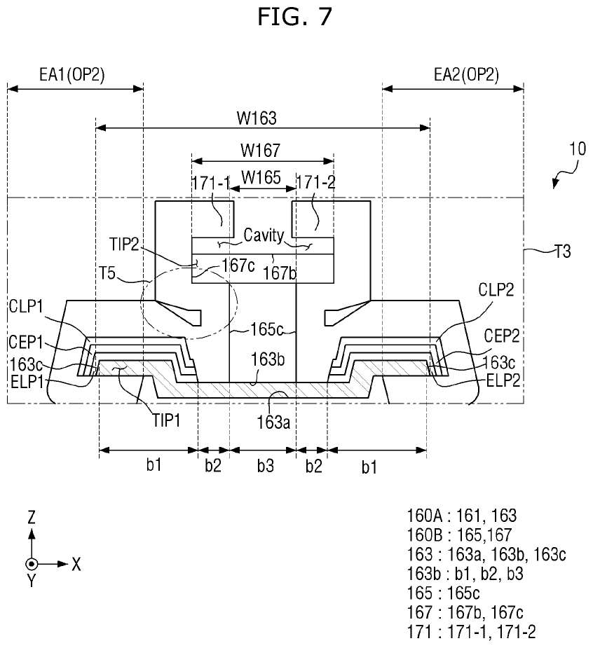

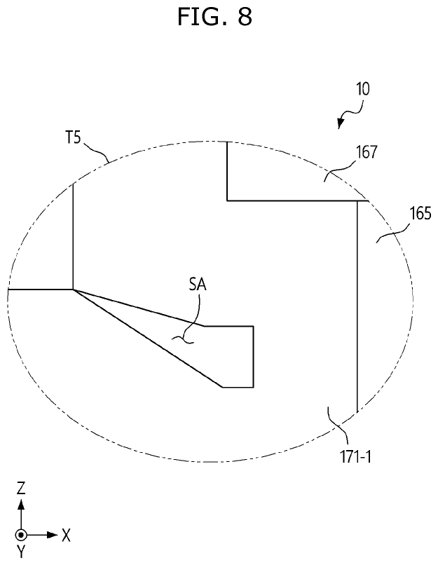

FIG. 6 is an enlarged cross-sectional view of the portion ‘T1’ of FIG. 5. FIG. 7 is an enlarged cross-sectional view of the portion ‘T3’ of FIG. 6. FIG. 8 is an enlarged cross-sectional view of the portion ‘T5’ of FIG. 7.

Referring to FIG. 6, in an embodiment, the inorganic pixel defining layer 151 may be disposed or positioned on the second passivation layer 139 and the first anode electrode AE1. A portion of the inorganic pixel defining layer 151 overlapping the second opening OP2 may be disposed or positioned to be spaced apart from the first anode electrode AE1 in the third direction (Z-axis direction). The residual pattern 157 may be disposed or positioned between the inorganic pixel defining layer 151 and the first anode electrode AE1.

The display device 10 may include a temporary protective layer between the inorganic pixel defining layer 151 and the first anode electrode AE1 during the manufacturing process. The temporary protective layer may be disposed between the inorganic pixel defining layer 151 and the first anode electrode AE1 and then removed by a subsequent wet etching process. A portion of the temporary protective layer that is not removed may remain as the residual pattern 157 between the inorganic pixel defining layer 151 and the first anode electrode AE1. In other words, since the residual pattern 157 is disposed or positioned between the inorganic pixel defining layer 151 and the first anode electrode AE1 of the display device 10, it would be understood that the display device 10 included the temporary protective layer during the manufacturing process.

The first light emitting layer EL1 may be disposed at a portion between the inorganic pixel defining layer 151 and the first anode electrode AE1 spaced apart from each other in the third direction (Z-axis direction). In an embodiment, as described above, the deposition process of forming the first light emitting layer EL1 may be performed so that the material of the first light emitting layer EL1 is deposited in the direction inclined between the first direction (X-axis direction) and the third direction (Z-axis direction). Accordingly, the first light emitting layer EL1 may be deposited while partially filling the portion between the first anode electrode AE1 and the inorganic pixel defining layer 151 spaced apart from each other. Accordingly, the residual pattern 157 and the first light emitting layer EL1 may be disposed or positioned to be in contact with each other in the portion between the first anode electrode AE1 and the inorganic pixel defining layer 151 spaced apart from each other. For convenience of description, the first anode electrode AE1 and the first light emitting layer EL1 have been described by way of example, but the anode electrodes AE1, AE2, and AE3 and the light emitting layers EL1, EL2, and EL3 may all have the same structure and characteristics as each other.

The first bank structure 160A may be disposed or positioned on the inorganic pixel defining layer 151. The first bank structure 160A may include the first bank layer 161 and the second bank layer 163 that include the different conductive materials, respectively.

The first bank layer 161 may be disposed or positioned to be in contact with the inorganic pixel defining layer 151. The first bank layer 161 may cover the inorganic pixel defining layer 151 at a same thickness along a profile of the inorganic pixel defining layer 151. Accordingly, the first bank layer 161 may include a step structure.

The first bank layer 161 may include the side surfaces 161c disposed or positioned toward the first openings OP1. The side surfaces 161c of the first bank layer 161 may be disposed or positioned in the form of an inclined surface inclined in the direction between the first direction (X-axis direction) and the third direction (Z-axis direction). The side surfaces 161c of the first bank layer 161 may be disposed or positioned to be depressed to one side in the first direction (X-axis direction) more than corresponding side surfaces of the inorganic pixel defining layer 151. Accordingly, the side surfaces 161c of the first bank layer 161 may partially expose the inorganic pixel defining layer 151 in portions overlapping the second openings OP2.

In an embodiment, as described above, the cathode electrodes CE1, CE2, and CE3 of the display device 10 may be deposited in the emission area EA1, EA2, and EA3, respectively, and may be electrically connected to each other through the first bank layer 161. Accordingly, the cathode electrodes CE1, CE2, and CE3 may be in contact with the side surfaces 161c of the first bank layer 161. In an embodiment, for example, as an area of the cathode electrodes CE1, CE2, and CE3 in contact with the side surfaces 161c of the first bank layer 161 increases, electrical resistance of the display device 10 may decrease. In addition, the light emitting layers EL1, EL2, and EL3, and the capping layers CPL1, CPL2, and CPL3 as well as the cathode electrodes CE1, CE2, and CE3 may be in contact with the side surfaces 161c of the first bank layer 161.

The second bank layer 163 may be disposed or positioned on the first bank layer 161. The second bank layer 163 may be disposed or positioned to be in contact with the first bank layer 161.

Referring to FIGS. 6 and 7, the second bank layer 163 may include an upper surface 163b, a lower surface 163a, and side surfaces 163c. The lower surface 163a of the second bank layer 163 may be a surface in contact with the first bank layer 161. In addition, the upper surface 163b of the second bank layer 163 may be a surface opposite to the lower surface 163a of the second bank layer 163. Like the first bank layer 161, the second bank layer 163 may cover the inorganic pixel defining layer 151 at a same thickness along the profile of the inorganic pixel defining layer 151. Accordingly, the upper surface 163b and the lower surface 163a of the second bank layer 163 may include a step structure.

The side surfaces 163c of the second bank layer 163 may be disposed or positioned toward the first openings OP1, and may connect the upper surface 163b and the lower surface 163a of the second bank layer 163 to each other.

In some embodiments, the first bank layer 161 and the second bank layer 163 may be formed through a wet etching process during the manufacturing process. Specifically, the first bank layer 161 and the second bank layer 163 included in the first bank structure 160A may be formed to cover the entirety of the emission areas EA1, EA2, and EA3 during the manufacturing process, and then formed to overlap only the non-emission area NLA in a structure included in an embodiment by subsequent photolithography and wet etching processes. In this process, the second bank layer 163 includes a material relatively stable to the wet etching process as compared with the first bank layer 161, and thus, the side surfaces 163c of the second bank layer 163 have a shape in which they protrude to opposing sides toward a center of the first openings OP1 more than the side surfaces 161c of the first bank layer 161. In other words, the side surfaces 161c of the first bank layer 161 may have a shape which is depressed more than the corresponding side surfaces 163c of the second bank layer 163 toward a center of the first bank structure 160A. Accordingly, the second bank layer 163 may include the tips TIP1 protruding toward the center of the first openings OP1 more than the side surfaces 161c of the first bank layer 161. The undercut structures may be formed between the lower portions of the tips TIP1 of the second bank layer 163 and the side surfaces 161c of the first bank layer 161.

Referring to FIG. 7, the upper surface 163b of the second bank layer 163 may include first portions b1, second portions b2, and a third portion b3 defined based on structures with which it is in contact.

In some embodiments, the first portions b1 of the upper surface 163b of the second bank layer 163 may be portions with which the organic patterns ELP1, ELP2, and ELP3 are in contact. In an embodiment, as illustrated in FIG. 7, the first portion b1 positioned (or defined) in another side of the upper surface 163b in the first direction (X-axis direction) may be in contact with the first organic pattern ELP1 and the first portion b1 positioned in one side of the upper surface 163b in the first direction (X-axis direction) may be in contact with the second organic pattern ELP2, but the disclosure is not limited thereto. That is, the first portion b1 positioned in another side of the upper surface 163b in the first direction (X-axis direction) may be in contact with one of the organic patterns ELP1, ELP2, and ELP3, and the first portion b1 positioned in one side of the upper surface 163b in the first direction (X-axis direction) may be in contact with another of the organic patterns ELP1, ELP2, and ELP3 different from the one of the organic patterns ELP1, ELP2, and ELP3 positioned in another side of the upper surface 163b.

The second portions b2 of the upper surface 163b of the second bank layer 163 may be portions in contact with the first encapsulation layer 171. The third portion b3 of the upper surface 163b may be a portion with which the third bank layer 165 of the second bank structure 160B is in contact. The third portion b3 of the upper surface 163b of the second bank layer 163 may be positioned between the second portions b2 positioned on opposing sides thereof.

In general, in a case where the second bank structure 160B is not formed on the first bank structure 160A, the upper surface 163b of the second bank layer 163 may include only the first portions b1 and the second portions b2. In other words, a portion of the upper surface 163b of the second bank layer 163 is in a state being covered with only the first encapsulation layer 171, and may be exposed to subsequent photolithography and etching processes. Accordingly, a portion of the upper surface 163b may be easily damaged, and may become a permeation path of moisture and oxygen.

In embodiments of the invention, the display device 10, as disclosed herein, includes the second bank structure 160B on the first bank structure 160A, and thus, the upper surface 163b of the second bank layer 163 may be protected to be exposed as less as possible during the manufacturing process.

In some embodiments, a width W163 of the second bank layer 163 may be greater than a width W165 of the third bank layer 165 included in the second bank structure 160B and a width W167 of the fourth bank layer 167 included in the second bank structure 160B.

The second bank structure 160B may be disposed or positioned to be in contact with the upper surface 163b of the second bank layer 163. In addition, the second bank structure 160B may be disposed or positioned between a plurality of first patterns ELP1, CEP1, and CLP1 overlapping the first emission area EA1 and a plurality of second patterns ELP2, CEP2, and CLP2 overlapping the second emission area EA2, in the first direction (X-axis direction). The second bank structure 160B may include the third bank layer 165 and the fourth bank layer 167 that include different inorganic films, respectively.

Referring to FIGS. 6 and 7, the third bank layer 165 may be disposed or positioned to be in contact with the upper surface 163b of the second bank layer 163. The third bank layer 165 may include side surfaces 165c disposed or positioned toward the second openings OP2. In an embodiment, as illustrated in FIGS. 6 and 7, the side surfaces 165c of the third bank layer 165 may be perpendicular to the second bank layer 163, but the disclosure is not limited thereto. In another embodiment, the side surfaces 165c of the third bank layer 165 may be inclined surfaces having an inclined shape.

The third bank layer 165 may include a silicon-based inorganic film containing oxygen. In an embodiment, for example, the third bank layer 165 may include silicon oxynitride (SiON) and silicon oxide (SiO₂). In an embodiment, for example, a content of oxygen in the third bank layer 165 may be about 33% or greater.

In some embodiments, the third bank layer 165 may be disposed to cover the first bank structure 160A and the anode electrodes AE1, AE2, and AE3 during the manufacturing process, and then formed in the shape of the third bank layer 165 illustrated in the drawings through photolithography and dry etching processes included in subsequent processes.

In an embodiment, as shown in FIG. 7, the fourth bank layer 167 may be positioned on the third bank layer 165. The fourth bank layer 167 may include an upper surface 167b and side surfaces 167c. The upper surface 167b of the fourth bank layer 167 may be one surface opposite to the second encapsulation layer 173. The side surfaces 167c of the fourth bank layer 167 may be disposed or positioned to protrude toward the center of the first openings OP1 more than the side surfaces 165c of the third bank layer 165. In an embodiment, as illustrated in FIGS. 6 and 7, the side surfaces 167c of the fourth bank layer 167 may be perpendicular in the third direction (Z-axis direction), but the disclosure is not limited thereto. In another embodiment, the side surfaces 167c of the fourth bank layer 167 may be inclined surfaces having an inclined shape.

The fourth bank layer 167 may include a silicon-based inorganic film containing nitrogen. In an embodiment, for example, the fourth bank layer 167 may include silicon nitride (Si₃N₄) and silicon oxynitride (SiON). In an embodiment, for example, a content of nitrogen in the fourth bank layer 167 may be about 33% or greater. The fourth bank layer 167 may have an etch rate relatively lower than that of the third bank layer 165.

In some embodiments, the fourth bank layer 167 may be disposed to cover the entirety of the third bank layer 165 and the anode electrodes AE1, AE2, and AE3 during the manufacturing process, and then formed in the shape of the fourth bank layer 167 illustrated in the drawings through photolithography and dry etching processes included in subsequent processes. The third bank layer 165 and the fourth bank layer 167 may be formed in the same manufacturing process, but etch rates of the third bank layer 165 and the fourth bank layer 167 may be different from each other depending on physical properties of materials of the third bank layer 165 and the fourth bank layer 167. Specifically, the etch rate of the third bank layer 165 including an inorganic film having a high oxygen content may be greater than that of the fourth bank layer 167 including an inorganic film having a high nitrogen content.

In an embodiment, as described above, the fourth bank layer 167 includes a material relatively stable to the dry etching process as compared with the third bank layer 165, and thus, the side surfaces 167c of the fourth bank layer 167 may have a shape protruding toward the center of the first openings OP1 and the second openings OP2 more than the side surfaces 165c of the third bank layer 165. In other words, the side surfaces 165c of the third bank layer 165 may have a shape depressed more than the side surfaces 167c of the fourth bank layer 167 toward the center of the second bank structure 160B. Accordingly, the fourth bank layer 167 may include the tips TIP2 protruding toward the center of the first openings OP1 and the second openings OP2 more than the side surfaces 165c of the third bank layer 165. The undercut structures may be formed between the lower portions of the tips TIP2 of the fourth bank layer 167 and the side surfaces 165c of the third bank layer 165. The width W165 of the third bank layer 165 may be smaller than the width W167 of the fourth bank layer 167.

In an embodiment, as described above, the first encapsulation layer 171 may include the first to third inorganic layers 171-1, 171-2, and 171-3. The first to third inorganic layers 171-1, 171-2, and 171-3 may be formed in different processes, respectively. Specifically, the first inorganic layer 171-1 may be formed to cover the second emission area EA2 and the third emission area EA3 after the first capping layer CPL1 is formed, and then removed in portions other than a portion overlapping the first emission area EA1 by subsequent photolithography and dry etching processes. In addition, the second inorganic layer 171-2 may be formed to cover the first emission area EA1 and the third emission area EA3 after the second capping layer CPL2 is formed, and then removed in portions other than a portion overlapping the second emission area EA2 by subsequent photolithography and dry etching processes. Furthermore, the third inorganic layer 171-3 may be formed to cover the first emission area EA1 and the second emission area EA2 after the third capping layer CPL3 is formed, and then removed in portions other than a portion overlapping the third emission area EA3 by subsequent photolithography and dry etching processes.

Accordingly, the first inorganic layer 171-1 and the second inorganic layer 171-2 may be spaced apart from each other in the first direction (X-axis direction) in a portion overlapping the non-emission area NLA. Specifically, the first inorganic layer 171-1 and the second inorganic layer 171-2 may be spaced apart from each other in the first direction (X-axis direction) on the upper surface 167b of the fourth bank layer 167. For convenience of description, only the first inorganic layer 171-1 and the second inorganic layer 171-2 have been described, but the third inorganic layer 171-3 may also have the same structure and characteristics as those of the first inorganic layer 171-1 and the second inorganic layer 171-2.

The first to third inorganic layers 171-1, 171-2, and 171-3 may cover lower structures along profiles of the lower structures. In an embodiment, as illustrated in FIG. 6, the first inorganic layer 171-1 may cover the lower structure along the profile of the lower structure in a portion overlapping the first emission area EA1, and the second inorganic layer 171-2 may cover the lower structure along the profile of the lower structure in a portion overlapping the second emission area EA2. Specifically, the first inorganic layer 171-1 may be in contact with and cover the first capping layer CPL1, the side surface 161c of the first bank layer 161, the lower surface 163a of the second bank layer 163, and the plurality of first patterns ELP1, CEP1, and CLP1 in a portion overlapping the first emission area EA1, and the second inorganic layer 171-2 may be in contact with and cover the second capping layer CPL2, the side surface 161c of the first bank layer 161, the lower surface 163a of the second bank layer 163, and the plurality of second patterns ELP2, CEP2, and CLP2 in a portion overlapping the second emission area EA2.

In addition, the first inorganic layer 171-1 may cover the plurality of first patterns ELP1, CEP1, and CLP1, the side surface 165c of the third bank layer 165, and the protruding tip TIP2 of the fourth bank layer 167 in a portion overlapping the non-emission area NLA, and the second inorganic layer 171-2 may cover the plurality of second patterns ELP2, CEP2, and CLP2, the side surface 165c of the third bank layer 165, and the protruding tip TIP2 of the fourth bank layer 167 in a portion overlapping the non-emission area NLA.

Referring to FIG. 7, the first to third inorganic layers 171-1, 171-2, and 171-3 may be disposed or positioned to be spaced apart from the upper surface 167b of the fourth bank layer 167 in the third direction (Z-axis direction). Accordingly, cavities may be defined or formed between the first to third inorganic layers 171-1, 171-2, and 171-3 and the upper surface 167b of the fourth bank layer 167.

In some embodiments, in the manufacturing process of the display device 10, after the first bank structure 160A is formed, the second bank structure 160B may be formed, and subsequently, the first light emitting layer EL1, the first cathode electrode CE1, and the first capping layer CPL1 may be sequentially formed. In such a process, the plurality of patterns ELP, CEP, and CLP may be formed not only on the upper surface 163b of the second bank layer 163 but also on the upper surface 167b of the fourth bank layer 167. However, the plurality of patterns ELP, CEP, and CLP formed on the upper surface 167b of the fourth bank layer 167 may be removed by subsequent photolithography and dry etching processes performed after the first encapsulation layer 171 is formed. Accordingly, the cavities may be formed between the first encapsulation layer 171 and the upper surface 167b of the fourth bank layer 167. In other words, since the cavities are defined between the first encapsulation layer 171 and the upper surface 167b of the fourth bank layer 167, it would be understood that the plurality of patterns ELP, CEP, and CLP were provided or positioned on the upper surface 167b of the fourth bank layer 167.

The second encapsulation layer 173 may be disposed or positioned on the first encapsulation layer 171. The second encapsulation layer 173 may cover the first encapsulation layer 171 along a profile of the first encapsulation layer 171. Specifically, the second encapsulation layer 173 may cover the first to third inorganic layers 171-1, 171-2, and 171-3 in portions overlapping the emission areas EA1, EA2, and EA3, and may be disposed or positioned between the first to third inorganic layers 171-1, 171-2, and 171-3 spaced apart from each other in portions overlapping the non-emission area NLA. In addition, the second encapsulation layer 173 may fill the cavities in the portions overlapping the non-emission area NLA.

In some embodiments, the first encapsulation layer 171 may form spaces SA in portions overlapping the non-emission area NLA. Specifically, the first encapsulation layer 171 may form the spaces SA under tips TIP2 of the fourth bank layer 167. In an embodiment, for example, the spaces SA may be formed as the first encapsulation layer 171 covers the plurality of patterns ELP, CEP, and CLP, the upper surface 163b of the second bank layer 163, the side surfaces 165c of the third bank layer 165, and the protruding tips TIP2 of the fourth bank layer 167 along profiles of the plurality of patterns ELP, CEP, and CLP, the upper surface 163b of the second bank layer 163, the side surfaces 165c of the third bank layer 165, and the protruding tips TIP2 of the fourth bank layer 167. In an embodiment, as illustrated in FIG. 8, the space SA may be completely surrounded by the first encapsulation layer 171. In an embodiment, for example, the space SA may be filled with nitrogen or air depending on a manufacturing environment of the display device 10, but is not limited thereto.

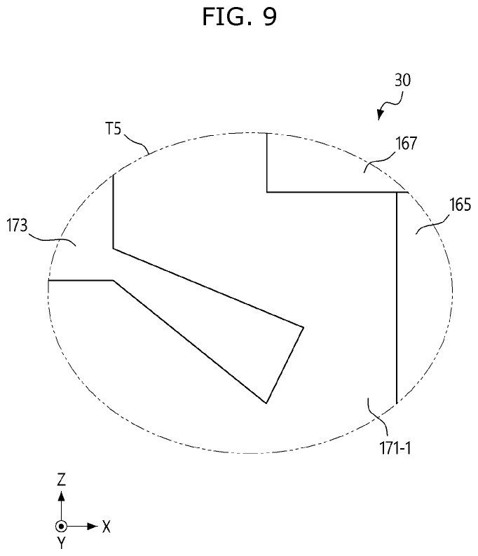

FIG. 9 is an enlarged cross-sectional view of the portion ‘T5’ of FIG. 7 according to another embodiment.

Referring to FIG. 9, another embodiment of a display device 30 is substantially the same as the display device 10 according to the above-described embodiment except that the first encapsulation layer 171 does not form the spaces SA in portions overlapping the non-emission area NLA. Specifically, the display device 30 of FIG. 9 is the same as the display device 10 according to the above-described embodiment in that the first encapsulation layer 171 covers the plurality of patterns ELP, CEP, and CLP, the upper surface 163b of the second bank layer 163, the side surfaces 165c of the third bank layer 165, and the protruding tips TIP2 of the fourth bank layer 167 along profiles of the plurality of patterns ELP, CEP, and CLP, the upper surface 163b of the second bank layer 163, the side surfaces 165c of the third bank layer 165, and the protruding tips TIP2 of the fourth bank layer 167, but is different from the display device 10 according to the above-described embodiment in that the first encapsulation layer 171 forms narrow gaps rather than the spaces SA, and covers a lower structure along a profile of the lower structure. The narrow gap formed by the first encapsulation layer 171 of the display device 30 may be filled with the second encapsulation layer 173. This may be adjusted according to the profile of the lower structure to be covered by the first encapsulation layer 171 during a manufacturing process.

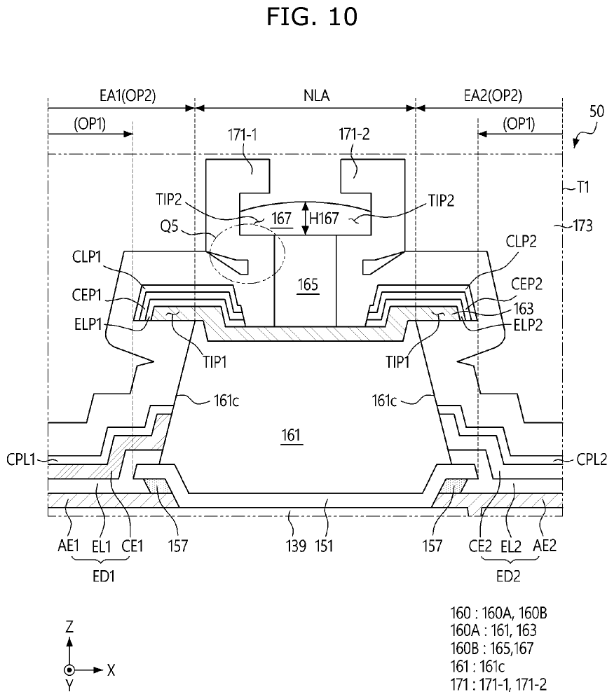

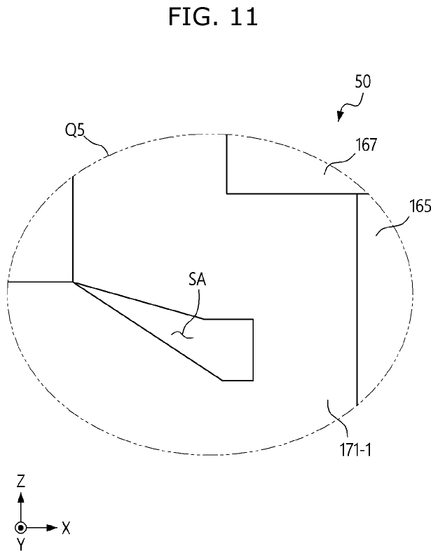

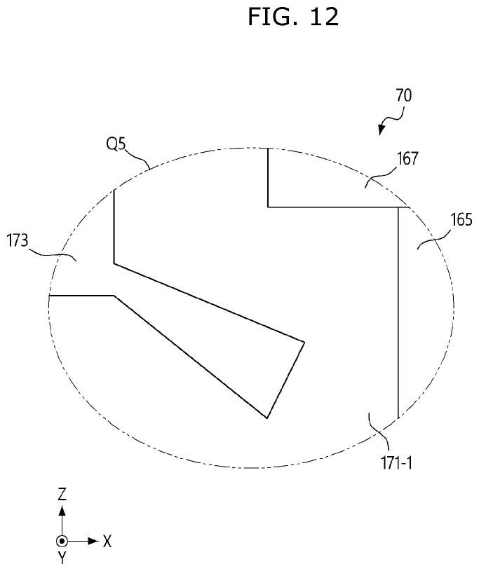

FIG. 10 is an enlarged cross-sectional view of the portion ‘T1’ of FIG. 5 according to another embodiment. FIG. 11 is an enlarged cross-sectional view of the portion ‘Q5’ of FIG. 10. FIG. 12 is an enlarged cross-sectional view of the portion ‘Q5’ of FIG. 10 according to another embodiment.

Referring to FIG. 10, another embodiment of a display device 50 is substantially the same as the display device according to the above-described embodiment except that the second bank structure 160B includes a third bank layer 165 and a fourth bank layer 167 including different materials from those described above.

The third bank layer 165 according to an embodiment may include an organic material or an inorganic material. In an embodiment, for example, the organic material of the third bank layer 165 may include an acrylic resin, a silicon-based resin, or a silicon acrylic resin, and the inorganic material of the third bank layer 165 may include silicon oxide, silicon nitride, or silicon oxynitride.

In some embodiments, the third bank layer 165 of the display device 50 may be disposed to cover the first bank structure 160A and the anode electrodes AE1, AE2, and AE3 during a manufacturing process, and then formed in the shape of the third bank layer 165 illustrated in FIG. 10 through photolithography and dry etching processes included in subsequent processes. Other features thereof are substantially the same as those described above, and any repetitive detailed descriptions thereof will be omitted.

The fourth bank layer 167 of the display device 50 may include an organic material. The organic material of the fourth bank layer 167 may include an acrylic resin, a silicon-based resin, or a silicon acrylic resin.

In some embodiments, the fourth bank layer 167 may be disposed to cover the entirety of the third bank layer 165 and the anode electrodes AE1, AE2, and AE3 during the manufacturing process, and then formed in the shape of the fourth bank layer 167 illustrated in FIG. 10 through photolithography and dry etching processes included in subsequent processes. The third bank layer 165 and the fourth bank layer 167 may be formed in a same manufacturing process as each other, but etch rates of the third bank layer 165 and the fourth bank layer 167 may be different from each other depending on physical properties of materials of the third bank layer 165 and the fourth bank layer 167. In an embodiment, the etch rate of the third bank layer 165 may be greater than that of the fourth bank layer 167.

In some embodiments, a thickness H167 of the fourth bank layer 167 may decrease toward the first encapsulation layer 171 in the first direction (X-axis direction). This may be caused by the fourth bank layer 167 including the organic material. However, the disclosure is not limited thereto, and the thickness H167 of the fourth bank layer 167 may also become uniform through a subsequent process.

Referring to FIG. 11, the first encapsulation layer 171 of the display device 50 may form spaces SA in portions overlapping the non-emission area NLA. Specifically, the first encapsulation layer 171 may form the spaces SA under the tips TIP2 of the fourth bank layer 167.

In some embodiments, the spaces SA may be formed as the first encapsulation layer 171 covers the plurality of patterns ELP, CEP, and CLP, the upper surface 163b of the second bank layer 163, the side surfaces 165c of the third bank layer 165, and the protruding tips TIP2 of the fourth bank layer 167 along profiles of the plurality of patterns ELP, CEP, and CLP, the upper surface 163b of the second bank layer 163, the side surfaces 165c of the third bank layer 165, and the protruding tips TIP2 of the fourth bank layer 167. In an embodiment, as illustrated in FIG. 11, the space SA may be completely surrounded by the first encapsulation layer 171. In an embodiment, for example, the space SA may be filled with nitrogen or air depending on a manufacturing environment of the display device 50, but is not limited thereto. Other features thereof are substantially the same as those described above, and any repetitive detailed descriptions thereof will be omitted.

Referring to FIG. 12, a display device 70 is different from the display device 50 according to the above-described embodiment in that the first encapsulation layer 171 does not form the spaces SA in portions overlapping the non-emission area NLA. Specifically, the display device 70 is the same as the display device 50 according to the above-described embodiment in that the first encapsulation layer 171 covers the plurality of patterns ELP, CEP, and CLP, the upper surface 163b of the second bank layer 163, the side surfaces 165c of the third bank layer 165, and the protruding tips TIP2 of the fourth bank layer 167 along profiles of the plurality of patterns ELP, CEP, and CLP, the upper surface 163b of the second bank layer 163, the side surfaces 165c of the third bank layer 165, and the protruding tips TIP2 of the fourth bank layer 167, but is different from the display device 50 according to the above-described embodiment in that the first encapsulation layer 171 forms narrow gaps rather than the spaces SA, and covers a lower structure along a profile of the lower structure. The narrow gap formed by the first encapsulation layer 171 of the display device 70 may be filled with the second encapsulation layer 173. This may be adjusted according to the profile of the lower structure of the display device 70 to be covered by the first encapsulation layer 171 during a manufacturing process.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate including an emission area and a non-emission area;
an anode electrode positioned on the emission area of the substrate;
a pixel defining layer positioned on the anode electrode and overlapping the non-emission area, wherein a first opening is defined through the pixel defining layer;
a first bank structure positioned on the pixel defining layer, and including at least two different conductive materials, wherein a second opening is defined through the first bank structure;
a second bank structure positioned on the first bank structure and including at least two different materials; and
a first encapsulation layer positioned on the second bank structure,
wherein the first bank structure includes a first bank layer and a second bank layer including a first tip protruding toward a center of the first opening more than a side surface of the first bank layer is,
the second bank structure includes a third bank layer and a fourth bank layer including a second tip protruding toward a center of the second opening more than a side surface of the third bank layer is, and
the first encapsulation layer covers the first tip and the second tip.

2. The display device of claim 1, further comprising:
a first light emitting layer positioned on the anode electrode to overlap the first opening;
a cathode electrode positioned on the first light emitting layer;
a first organic pattern positioned on the second bank layer while surrounding the first opening, and including a same material as the first light emitting layer; and
a first electrode pattern positioned on the first organic pattern while surrounding the first opening, and including a same material as the cathode electrode.

3. The display device of claim 2, wherein the first light emitting layer and the cathode electrode are in contact with the side surface of the first bank layer.

4. The display device of claim 3, wherein
the first organic pattern is spaced apart from the first light emitting layer,
the first electrode pattern is spaced apart from the cathode electrode, and
the first organic pattern and the first electrode pattern overlap the first tip.

5. The display device of claim 4, wherein
the first bank layer includes aluminum, and
the second bank layer includes titanium.

6. The display device of claim 1, wherein the first encapsulation layer is in contact with the side surface of the first bank layer and the first tip of the second bank layer.

7. The display device of claim 2, wherein
the second bank layer includes a first surface opposite to the third bank layer, and
the first surface includes:
a first portion, with which the first organic pattern is in contact;
a second portion, with which the first encapsulation layer is in contact; and
a third portion, with which the third bank layer is in contact.

8. The display device of claim 7, wherein
the second portion is positioned between the first portion and the third portion, and
the first portion, the second portion, and the third portion are integrally formed as a single unitary and indivisible part.

9. The display device of claim 8, wherein the first encapsulation layer is in contact with the side surface of the third bank layer.

10. The display device of claim 1, wherein a cavity is defined between the fourth bank layer and the first encapsulation layer to overlap the second tip.

11. The display device of claim 10, further comprising:
a second encapsulation layer positioned on the first encapsulation layer,
wherein the cavity is filled with the second encapsulation layer.

12. The display device of claim 1, wherein a space completely surrounded by the first encapsulation layer is defined between the second bank layer and the fourth bank layer in a direction perpendicular to the substrate.

13. The display device of claim 1, wherein
the third bank layer includes an inorganic film including about 33% or greater of oxygen,
the fourth bank layer includes an inorganic film including about 33% or greater of nitrogen.

14. The display device of claim 1, wherein
the third bank layer includes an organic material or an inorganic material, and
the fourth bank layer includes an organic material.

15. The display device of claim 1, wherein a width of the third bank layer is less than a width of the fourth bank layer.

16. The display device of claim 15, wherein
the first bank layer and the second bank layer overlap the emission area, and
the third bank layer and the fourth bank layer do not overlap the emission area.

17. A display device comprising:
a substrate including a first emission area, a second emission area, and a non-emission area positioned between the first emission area and the second emission area;
a first anode electrode positioned on the first emission area of the substrate;
a second anode electrode positioned on the second emission area of the substrate;
a pixel defining layer positioned on the non-emission area of the substrate between the first anode electrode and the second anode electrode, wherein openings are defined through the pixel defining layer;
a first bank structure positioned on the pixel defining layer and including at least two different conductive materials;
a second bank structure positioned on the first bank structure and including at least two different inorganic films; and
a first encapsulation layer positioned on the second bank structure,
wherein the first bank structure includes a first bank layer and a second bank layer including first tips, each protruding toward a center of a corresponding one of the openings more than a corresponding one of side surfaces of the first bank layer is,
the second bank structure includes a third bank layer and a fourth bank layer including second tips, each protruding toward a center of a corresponding one of the openings more than a corresponding one of side surfaces of the third bank layer is, and
the first encapsulation layer covers the first tips and the second tips.

18. The display device of claim 17, wherein the first encapsulation layer includes:
a first inorganic layer overlapping the first emission area; and
a second inorganic layer overlapping the second emission area, and
a portion of the first inorganic layer overlapping the fourth bank layer and a portion of the second inorganic layer overlapping the fourth bank layer are spaced apart from each other.

19. The display device of claim 18, further comprising:
a first light emitting layer positioned on the first anode electrode;
a second light emitting layer positioned on the second anode electrode;
a first organic pattern positioned on the second bank layer to overlap the first emission area, including a same material as the first light emitting layer, and spaced apart from the first light emitting layer; and
a second organic pattern positioned on the second bank layer to overlap the second emission area, including a same material as the second light emitting layer, and spaced apart from the second light emitting layer,
wherein the third bank layer is positioned between the first organic pattern and the second organic pattern.

20. The display device of claim 19, further comprising:
a first light emitting element including the first anode electrode and the first light emitting layer; and
a second light emitting element including the second anode electrode and the second light emitting layer,
wherein in a plan view, the first light emitting element and the second light emitting element are completely surrounded by the pixel defining layer, and
in the plan view, the pixel defining layer is completely surrounded by the first bank structure.
